(19) United States
(12) Patent Application Publication
(10) Pub. No.: US 2026/0063947 A1
(43) Pub. Date: Mar. 5, 2026

(54) DISPLAY APPARATUS

(71) Applicant: SAMSUNG ELECTRONICS CO., LTD., Suwon-si (KR)

(72) Inventors: Dukjin JEON, Suwon-si (KR); Ajeong KANG, Suwon-si (KR); Sunghee WI, Suwon-si (KR); Youngmin LEE, Suwon-si (KR)

(73) Assignee: SAMSUNG ELECTRONICS CO., LTD., Suwon-si (KR)

(21) Appl. No.: 19/258,374

(22) Filed: Jul. 2, 2025

Related U.S. Application Data
(63) Continuation of application No. PCT/KR2025/008579, filed on Jun. 20, 2025.

(30) Foreign Application Priority Data
Jul. 26, 2024 (KR) 10-2024-0099782

(51) Int. Cl. G02F 1/13357; G02F 1/1335; H10H 20/856

(52) U.S. Cl. CPC G02F 1/133603; G02F 1/133607; G02F 1/133613; H10H 20/856

(57) ABSTRACT

A display apparatus includes a display panel and a light source device that provides light to the display panel. The light source device includes a substrate and a plurality of first light sources on the substrate. The plurality of first light sources each include a first light-emitting diode and an anisotropic reflection lens configured to cover the first light-emitting diode. The light source device includes a second light source on the substrate and provided between two adjacent first light sources among the plurality of first light sources. The second light source includes a second light-emitting diode and a refractive lens configured to cover the second light-emitting diode.

### CROSS-REFERENCE TO RELATED APPLICATIONS

This application is a continuation application of International Application No. PCT/KR2025/008579, filed on Jun. 20, 2025, which claims priority to Korean Patent Application No. 10-2024-0099782, filed on Jul. 26, 2024, in the Korean Intellectual Property Office, the disclosures of which are incorporated by reference herein in their entireties.

### BACKGROUND

### 1. Field

The present disclosure relates to a display apparatus, and more particularly, to a display apparatus including a display panel and a light source device.

### 2. Description of Related Art

A display apparatus is an output device that converts acquired or stored electrical information into visual information and displays the visual information to a user. Display apparatuses are used in various fields such as homes and workplaces.

With display apparatuses, there are monitor devices connected to personal computers, server computers, or the like, portable computer devices, navigation terminal devices, general television devices, Internet protocol television (IPTV) devices, portable terminal devices, such as smartphones, tablet PCs, personal digital assistant (PDA) devices, or cellular phones, various types of display apparatuses used to play images such as advertisements or movies in industrial sites, or various types of audio/video systems.

The display apparatus includes a light source module to convert electrical information into visual information, and the light source module includes a plurality of light sources configured to emit light independently.

For example, the plurality of light sources include light-emitting diodes (LEDs) or organic light-emitting diodes (OLEDs). For example, the light-emitting diode or the organic light-emitting diode may be mounted on a substrate (or a circuit board).

### SUMMARY

The present disclosure provides a display apparatus with an improved structure.

The present disclosure provides a display apparatus with improved luminous efficiency.

The present disclosure provides a display apparatus having uniform luminance.

Technical problems to be solved by the present disclosure are not limited to the above-mentioned technical problems, and other technical problems, which are not mentioned above, may be clearly understood from the following descriptions by those skilled in the art to which the present disclosure pertains.

According to an aspect of the disclosure, there is provided a display apparatus including: a display panel; and a light source device configured to provide light to the display panel, wherein the light source device includes: a substrate; a plurality of first light sources on the substrate, the plurality of first light sources each including a first light-emitting diode and an anisotropic reflection lens configured to cover the first light-emitting diode; and a second light source on the substrate and provided between two adjacent first light sources among the plurality of first light sources, the second light source including a second light-emitting diode and a refractive lens configured to cover the second light-emitting diode.

The display panel may include: a pair of long sides extending in a first direction; and a pair of short sides extending in a second direction, wherein the plurality of first light sources are spaced apart from each other in the first direction, and wherein among the plurality of first light sources, a first distance in the first direction between one first light source and another first light source adjacent to the one first light source may be longer than a second distance in the first direction between the second light source and another first light source adjacent to the second light source.

The second light source may be provided at a center between the two adjacent first light sources among the plurality of first light sources.

The second light source may be disposed to correspond to a halfway point of the display panel in the first direction and correspond to a halfway point of the display panel in the second direction.

The light source device may be provided as a plurality of light source devices, wherein the plurality of light source devices are spaced apart from each other in the second direction, and wherein the second light source of each light source device of the plurality of light source devices may be provided to correspond to a halfway point of the display panel in the first direction.

The second light source may be provided to correspond to a point spaced apart from a short side of the display panel by a ⅙ length of the display panel in the first direction and correspond to a point spaced apart from a long side of the display panel by a ⅙ length of the display panel in the second direction.

The second light source may be provided as a plurality of second light sources, wherein any one of the plurality of second light sources may be provided to correspond to a halfway point of the display panel in the first direction, wherein another one of the plurality of second light sources may be provided to correspond to a point spaced apart from a first short side of the display panel by a ⅙ length of the display panel in the first direction, and wherein another one of the plurality of second light sources may be provided to correspond to a point spaced apart from a second short side of the display panel by a ⅙ length of the display panel in the first direction.

The plurality of second light sources are provided to correspond to a halfway point of the display panel in the second direction.

The plurality of second light sources are provided to correspond to a point spaced apart from a long side of the display panel by a ⅙ length of the display panel in the second direction.

The light source device may be provided as a plurality of light source devices, wherein the plurality of light source devices are provided to be spaced apart from one another in the second direction, wherein the plurality of second light sources of any one of the plurality of light source devices are provided to correspond to a halfway point of the display panel in the second direction, wherein the plurality of second light sources of another one of the plurality of light source devices are each disposed to correspond to a point spaced apart from a first long side of the display panel by a ⅙ length of the display panel in the second direction, and wherein the plurality of second light sources of another one of the plurality of light source devices are each disposed to correspond to a point spaced apart from a second long side of the display panel by a ⅙ length of the display panel in the second direction.

The anisotropic reflection lens may include: a bottom portion provided on the substrate; and a groove portion recessed from the bottom portion to accommodate the first light-emitting diode.

A first length of the groove portion in the first direction may be shorter than a second length of the groove portion in the second direction.

The anisotropic reflection lens has a recessed shape, and wherein the refractive lens has a dome shape.

The light source device may be provided as a plurality of light source devices, wherein each substrate of a plurality of substrates have a bar shape extending in the first direction, and wherein the plurality of substrates are spaced apart from one another in the second direction.

The light source device may be provided as a plurality of light source devices, and wherein each substrate of a plurality of substrates have a plate shape having a plane in the first direction and the second direction.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a perspective view of a display apparatus according to an embodiment of the present disclosure;

FIG. 2 is an exploded view of an example of the display apparatus according to an embodiment of the present disclosure;

FIG. 3 is an exploded view of an example of the display apparatus according to an embodiment of the present disclosure;

FIG. 4 is a cross-sectional view of the display panel according to an embodiment of the present disclosure;

FIG. 5 is a perspective view of a light source device according to an embodiment of the present disclosure;

FIG. 6 is a cross-sectional view schematically illustrating a reflective sheet and a first light source of the light source device according to an embodiment of the present disclosure.

FIG. 7 is a cross-sectional view schematically illustrating the reflective sheet and the first light source of the light source device according to an embodiment of the present disclosure;

FIG. 8 is a cross-sectional view schematically illustrating the reflective sheet and a second light source of the light source device according to an embodiment of the present disclosure;

FIG. 9 is a front view schematically illustrating an example of the display apparatus according to an embodiment of the present disclosure;

FIG. 10 is a front view schematically illustrating an example of the display apparatus according to an embodiment of the present disclosure;

FIG. 11 is a front view schematically illustrating an example of the display apparatus according to an embodiment of the present disclosure;

FIG. 12 is a front view schematically illustrating an example of the display apparatus according to an embodiment of the present disclosure; and

FIG. 13 is a front view schematically illustrating an example of the display apparatus according to an embodiment of the present disclosure.

### DETAILED DESCRIPTION

Various embodiments of the present disclosure and the terms used in embodiments are not intended to limit the technical features disclosed in the present disclosure to the particular embodiments and should be understood as including various alterations, equivalents, or alternatives of the corresponding embodiments.

In connection with the description of the drawings, the same or similar reference numerals may be used for the similar or relevant components.

A singular form of a noun corresponding to an item may include one or more of the items, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases.

The term “and/or” includes any and all combinations of a plurality of related and listed components.

The terms “part,” “module,” and “member” may be implemented by hardware or software. According to embodiments, the plurality of “parts,” “modules,” or “member” may be implemented as a single component, or one “part,” “module,” or “member” may include a plurality of components.

As used herein, such terms as “1st” and “2nd,” or “first” and “second” may be used to simply distinguish a corresponding component from another, and does not limit the components in other aspect (e.g., importance or order).

If an element (e.g., a first element) is referred to, with or without the term “operatively” or “communicatively,” as “coupled with,” “coupled to,” “connected with,” or “connected to” another element (e.g., a second element), it means that the element may be coupled with the other element directly (e.g., wiredly), wirelessly, or via a third element.

The terms “including” and “having” are intended to designate the existence of characteristics, numbers, steps, operations, constituent elements, and components described in the present disclosure or a combination thereof, and do not exclude a possibility of the existence or addition of one or more other characteristics, numbers, steps, operations, constituent elements, and components, or a combination thereof in advance.

When one constituent element is “connected to,” coupled to,” “supported on,” or “in contact with” another constituent element, the constituent elements may be directly connected to, coupled to, supported on, or in contact with each other, and one constituent element may be indirectly connected to, coupled to, supported on, or in contact with another constituent element by means of a third constituent element.

When one constituent element is positioned “on” another constituent element, one constituent element may adjoin another constituent element, and still another constituent element may be present between the two constituent elements.

The terms “forward/rearward direction,” “forward,” “rearward,” and the like used in the following description are defined based on the drawings, and shapes and positions of the constituent elements are not limited by the terms.

For example, the terms “forward” and “rearward” may be defined based on an X direction illustrated in the drawings. For example, the terms “upward” and “downward” may be defined based on a Z direction illustrated in the drawings. For example, the terms “leftward direction” and “rightward direction” may be defined based on a Y direction illustrated in the drawings. For example, the term “vertical direction” may refer to the Z direction illustrated in the drawings. For example, the term “horizontal direction” may refer to the Y direction illustrated in the drawings.

Hereinafter, embodiments according to the present disclosure will be described in detail with reference to the accompanying drawings.

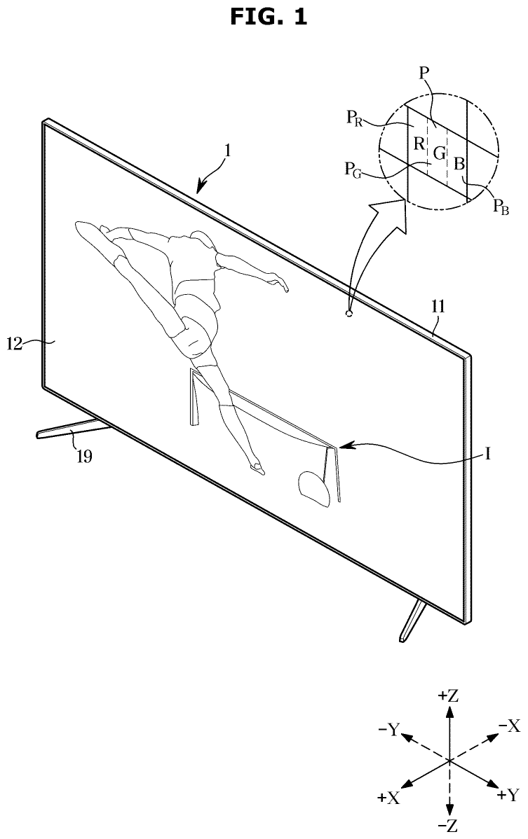

FIG. 1 is a perspective view of a display apparatus according to an embodiment of the present disclosure.

With reference to FIG. 1, a display apparatus 1 according to an embodiment of the present disclosure is a device capable of processing image signals received from the outside and visually displaying the processed images. FIG. 1 illustrates an example in which the display apparatus 1 is a television (TV). However, the present disclosure is not limited thereto. For example, the display apparatus 1 may be implemented in various shapes such as a monitor, which is a kind of computer output device, a portable multimedia device, or a portable communication device. The shape of the display apparatus 1 is not limited as long as the display apparatus 1 is a device that visually displays images.

Furthermore, the display apparatus 1 may be a large format display (LFD) installed outdoors, such as a building rooftop or a bus stop. In this case, the outdoor is not limited to the outside of the buildings. The display apparatus 1 according to an embodiment of the present disclosure may be installed in any place as long as the display apparatus 1 is accessed by a large number of people, even indoors, such as subway stations, shopping malls, movie theaters, companies, and stores.

FIG. 1 illustrates an example in which the display apparatus 1 is a flat display apparatus having a flat screen. However, the present disclosure is not limited thereto. The display apparatus according to the spirit of the present disclosure may also be applied to a curved display apparatus or a variable (bendable or flexible) display apparatus in which a flat state and a curved state may be changed. In addition, the configuration of the present disclosure may be applied to display apparatuses with various shapes regardless of a screen size or a screen ratio of the display apparatus.

The display apparatus 1 may receive content including video signals and audio signals from various content sources and output video and audio corresponding to the video signal and the audio signal. For example, the display apparatus 1 may receive content data through a broadcast receiving antenna or wired cable, receive content data from a content playback device, or receive content data from a content providing server of a content provider.

The display apparatus 1 may display images corresponding to the video data and output sounds corresponding to the audio data. For example, the display apparatus 1 may restore a plurality of image frames included in the video data and continuously display the plurality of image frames. In addition, the display apparatus 1 may restore audio signals included in the audio data and continuously output sounds according to the audio signals.

As illustrated in FIG. 1, the display apparatus 1 may include a main body 11, and a screen 12 configured to display an image I.

The display apparatus 1 may be installed to stand on indoor and outdoor floor surfaces or furniture or installed to be suspended on a wall surface or in a wall. For example, the display apparatus 1 may include support legs 19 provided on a lower portion of the main body 11 so that the display apparatus 1 may be installed to stand on the indoor or outdoor floor surface or the furniture.

The main body 11 may define an external shape of the display apparatus 1. Components, which serve to perform various types of functions such as a function of allowing the display apparatus 1 to display the image I, may be provided in the main body 11.

The display apparatus 1 may be configured to display the image I. Specifically, the screen 12 may be provided on a front surface of the main body 11, and the display apparatus 1 may display the image I by means of the screen 12. For example, the screen 12 may display a still image or a video. In addition, the screen 12 may display a two-dimensional flat image or a three-dimensional stereoscopic image by using a parallax difference between the user's two eyes.

A plurality of pixels P may be formed in the screen 12. The image I displayed on the screen 12 may be formed by light emitted from the plurality of pixels P. For example, the light beams emitted from the plurality of pixels P are combined like a mosaic, such that the image I may be formed on the screen 12.

The plurality of pixels P may emit light beams with various brightness and various colors. In detail, the plurality of pixels P may each include subpixels P_{R}, P_{G}, and P_{B}, and the subpixels P_{R}, P_{G}, and P_{B} may include a red subpixel P_{R} capable of emitting red light, a green subpixel P_{G} capable of emitting green light, and a blue subpixel P_{B} capable of emitting blue light. For example, the red light may refer to light with a wavelength of approximately 620 nm (nanometer, one billionth of a meter) to 750 nm, the green light may refer to light with a wavelength of approximately 495 nm to 570 nm, and the blue light may refer to light with a wavelength of approximately 450 nm to 495 nm.

The plurality of pixels P may each emit light beams with various brightness and various colors with the combination of the light beams emitted from the red subpixel P_{R}, the green subpixel P_{G}, and the blue subpixel P_{B}.

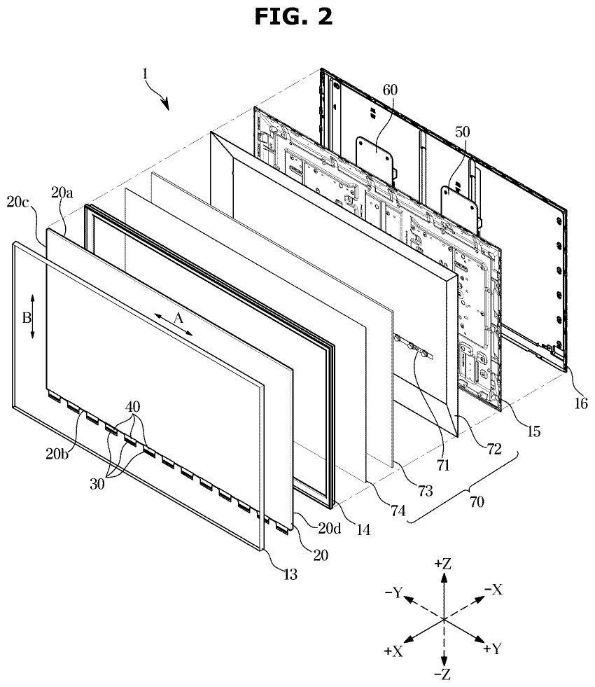

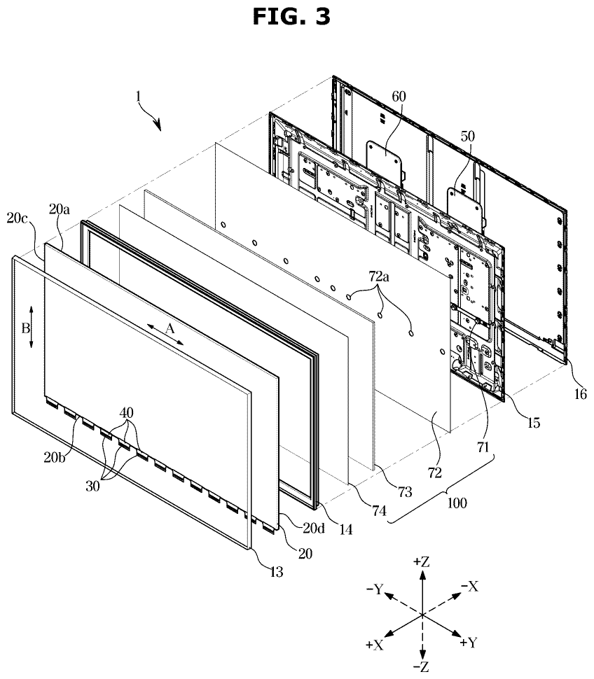

FIG. 2 is an exploded view of an example of the display apparatus according to an embodiment of the present disclosure. FIG. 3 is an exploded view of an example of the display apparatus according to an embodiment of the present disclosure.

With reference to FIGS. 2 and 3, various types of components for creating the image I on the screen 12 may be provided in the main body 11 of the display apparatus 1 according to an embodiment of the present disclosure.

For example, the display apparatus 1 may include a display panel 20. The display panel 20 may be provided in the main body 11. The display panel 20 may be provided to display the image I. The screen 12 illustrated in FIG. 1 may be formed on the front surface of the display panel 20.

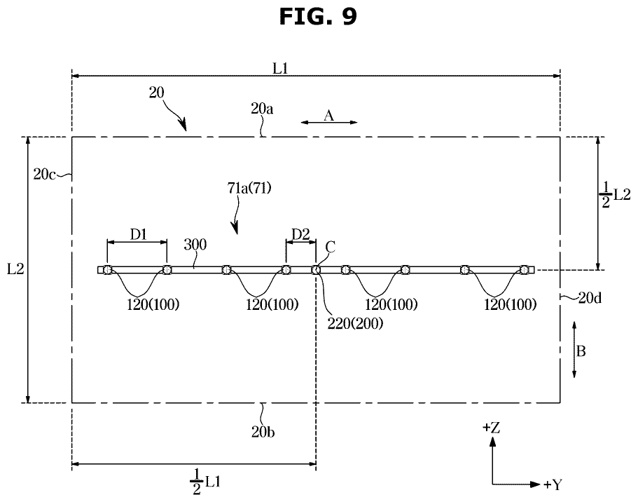

For example, the display panel 20 may have an approximately rectangular shape. The display panel 20 may have a shape in which a length (e.g., L1, see FIGS. 9 to 13) of a horizontal side and a length (e.g., L2, see FIGS. 9 to 13) of a vertical side are different from each other. The display panel 20 may include a pair of long sides 20a and 20b extending in a first direction A. The display panel 20 may include a first long side 20a and a second long side 20b. The display panel 20 may include a pair of short sides 20c and 20d extending in a second direction B. The display panel 20 may include a first short side 20c and a second short side 20d. The second direction B may be a direction intersecting the first direction A. The second direction B may be a direction approximately perpendicular to the first direction A. The drawings illustrate that the first direction A is an approximately horizontal direction (Y direction), and the second direction B is an approximately vertical direction (Z direction). However, the first direction A may be an approximately vertical direction (Z direction), and the second direction B may be an approximately horizontal direction (Y direction). However, the present disclosure is not limited to the above-mentioned example. The display panel 20 may have a square shape in which a length (e.g., L1, see FIGS. 9 to 13) of a horizontal side and a length (e.g., L2, see FIGS. 9 to 13) of a vertical side are almost equal to each other.

The display panel 20 may be provided to have various sizes. A ratio between the long side and the short side of the display panel 20 is not limited to a general case such as 16:9 or 4:3. On the contrary, the ratio may be provided as any ratio.

A cable 40 configured to transmit image data to the display panel 20 may be provided at a side of the display panel 20, and a display driver integrated circuit (DDI) 30 (hereinafter, referred to as a ‘driver IC’) configured to process digital image data and output an analog image signal may be provided at a side of the display panel 20.

The cable 40 may electrically connect a control assembly 50/a power source assembly 60 and the driver IC 30. In addition, the cable 40 may electrically connect the driver IC 30 and the display panel 20. The cable 40 may include a flexible flat cable, a film cable, or the like that may be bent.

The driver IC 30 may receive image data and electric power from the control assembly 50/the power source assembly 60 through the cable 40 and transmit image data and drive current to the display panel 20 through the cable 40.

The cable 40 and the driver IC 30 may be integrally implemented as a film cable, a chip-on-film (COF), a tape carrier package (TCP), or the like. In other words, the driver IC 30 may be disposed (e.g., provided) on a cable 20b. However, the present disclosure is not limited thereto. The driver IC 30 may be disposed on the display panel 20.

A specific description of a structure of the display panel 20 will be described below.

The display apparatus 1 may include a backlight unit 70. The backlight unit 70 may be provided to emit light toward the display panel 20. The backlight unit 70 may be provided in the main body 11. The backlight unit 70 may be disposed rearward of the display panel 20. The backlight unit 70 may be disposed rearward of the display panel 20 and provided to emit light toward the front side at which the display panel 20 is positioned. For example, the backlight unit 70 may be configured as a surface light source. The display panel 20 may block or transmit the light emitted from the backlight unit 70.

The backlight unit 70 may include a point light source configured to emit monochromatic light or white light and be configured to refract, reflect, and scatter the light in order to convert the light emitted from the point light source into uniform surface light. The backlight unit 70 may emit uniform surface light forward by refracting, reflecting, and scattering the light emitted from the point light source.

The backlight unit 70 may include a light source device 71. The light source device 71 may create and emit the light. For example, the light source device 71 may be provided to emit monochromatic light or white light. The light source device 71 may be provided to provide light to the display panel 20.

According to an embodiment of the present disclosure, the light source device 71 may be disposed rearward of the display panel 20. The light source device 71 may not be disposed to deviate from the sides 20a, 20b, 20c, and 20d of the display panel 20. The light source device 71 may be disposed inward of the sides 20a, 20b, 20c, and 20d of the display panel 20. That is, when the display apparatus 1 is viewed from the front side, the light source device 71 may be provided to be covered by the display panel 20 without being exposed from the display panel 20.

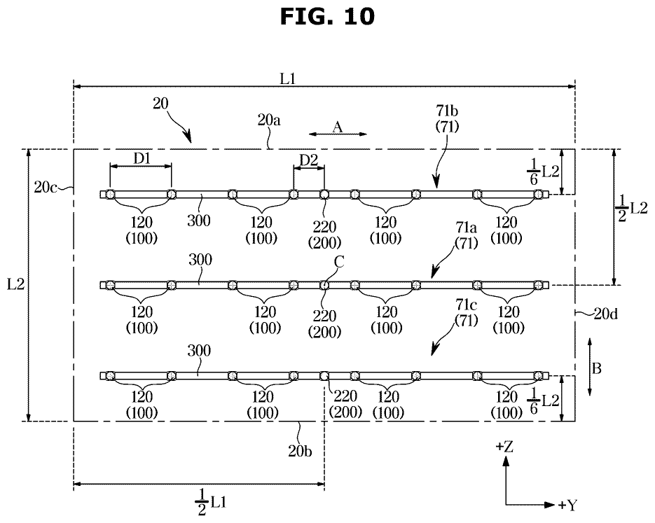

FIGS. 2 and 3 illustrate one light source device 71. However, the present disclosure is not limited thereto. The light source device 71 may be provided as a plurality of light source devices 71 (see FIGS. 10, 12, and 13).

The light source device 71 may be referred to as a light source module 71, a light source unit 71, a light source assembly 71, or the like.

The backlight unit 70 may include a reflective sheet 72. The reflective sheet 72 may be provided to reflect light. The reflective sheet 72 may reflect the light forward or in a direction similar to the forward direction. The reflective sheet 72 may reflect light emitted from the light source device 71 and/or light exiting rearward from a diffusion plate 73 to be described below toward the display panel 20.

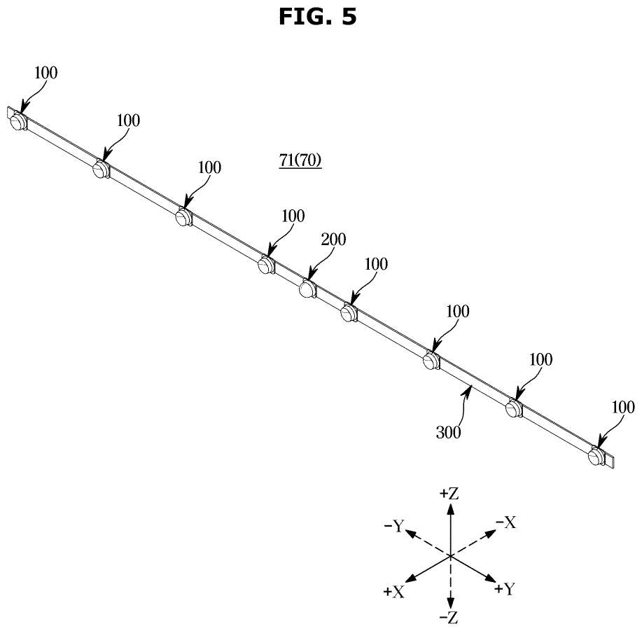

For example, the light source device 71 (in detail, a plurality of light sources 100 and 200 (see FIG. 5) of the light source device 71) may emit light in various directions. The light emitted from the light source device 71 may not only propagate toward the diffusion plate 73 but also propagate from the light source device 71 toward the reflective sheet 72. The reflective sheet 72 may reflect the light, which propagates toward the reflective sheet 72, toward the diffusion plate 73. Alternatively, the light emitted from the light source device 71 may pass through various objects such as the diffusion plate 73 and an optical sheet 74, and a part of the light may be reflected by surfaces of the diffusion plate 73, the optical sheet 74, and the like. The reflective sheet 72 may reflect the light, which is reflected as described above, forward again.

For example, with reference to FIG. 2, the reflective sheet 72 may be provided rearward of the light source device 71. The reflective sheet 72 may be disposed forward of a bottom chassis 15, and the light source device 71 may be disposed forward of the reflective sheet 72. The reflective sheet 72 may be disposed between the light source device 71 and the bottom chassis 15. The reflective sheet 72 may be disposed to cover a front surface of the bottom chassis 15.

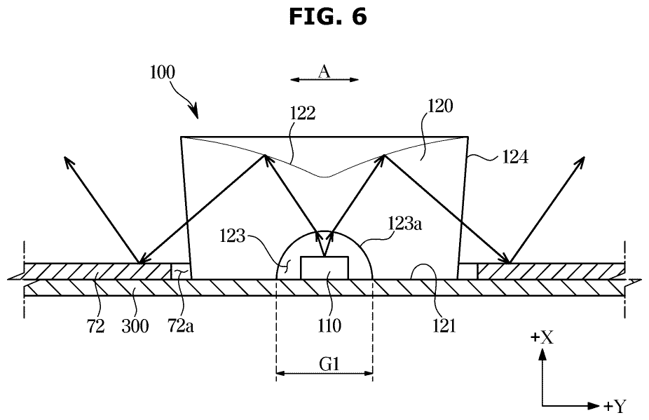

For example, with reference to FIG. 3, the reflective sheet 72 may be provided forward of a substrate 300 (see FIG. 5) of the light source device 71. The reflective sheet 72 may include a plurality of through-holes 72a respectively corresponding to the plurality of light sources 100 and 200 (see FIG. 5) of the light source device 71. The plurality of light sources 100 and 200 (see FIG. 5) may pass through the plurality of through-holes 72a and protrude forward from the reflective sheet 72 (see FIGS. 6 to 8). The light sources 100 and 200 of the light source device 71 and a part of the substrate 300 may be exposed forward from the reflective sheet 72 through the through-holes 72a (see FIGS. 6 to 8).

However, the reflective sheet 72 according to an embodiment of the present disclosure is not limited to that illustrated in FIGS. 2 and 3. The shape, position, and the like of the reflective sheet 72 are not limited as long as the reflective sheet 72 may reflect the light toward the display panel 20 and/or the optical member 73 and/or 74 to be described below.

The backlight unit 70 may include the diffusion plate 73. The diffusion plate 73 may be provided to uniformly diffuse the light. The diffusion plate 73 may be provided forward of the light source device 71 and the reflective sheet 72. The diffusion plate 73 may uniformly disperse the light emitted from the light source device 71 and then emit the light forward.

The backlight unit 70 may include the optical sheet 74. The optical sheet 74 may be provided to further improve luminance and uniformity of luminance of the emitted light. The optical sheet 74 may be provided to refract and scatter the light emitted from the front surface of the diffusion plate 73. For example, the optical sheet 74 may include various types of sheets such as a diffusion sheet, a prism sheet, a reflective polarizing sheet, and a quantum dot sheet.

The diffusion plate 73 and the optical sheet 74 may be referred to as optical members.

The display apparatus 1 may include the control assembly 50 configured to control operations of the backlight unit 70 and the display panel 20. The display apparatus 1 may include the power source assembly 60 configured to supply electric power to the backlight unit 70 and the display panel 20. The control assembly 50 and the power source assembly 60 may be provided in the main body 11. For example, the control assembly 50 and the power source assembly 60 may be provided between the bottom chassis 15 and a rear cover 16.

For example, the control assembly 50 may include a control circuit configured to control the operations of the display panel 20 and the backlight unit 70. The control circuit may process image data received from an external content source, transmit image data to the display panel 20, and transmit dimming data to the backlight unit 70.

For example, the power source assembly 60 may supply electric power to the display panel 20 and the backlight unit 70 so that the backlight unit 70 outputs the surface light, and the display panel 20 may block or transmit the light emitted from the backlight unit 70.

The control assembly 50 and the power source assembly 60 may be implemented by printed circuit boards and various types of circuits mounted on the printed circuit boards. For example, the power circuit may include a condenser, a coil, a resistor element, a processor, and the like, and a power circuit board on which these components are mounted. In addition, the control circuit may include a memory, a processor, and a control circuit substrate on which these components are mounted.

The display apparatus 1 may include a display casing provided to support various types of components of the main body 11 of the display apparatus 1. In order words, various types of components of the main body 11 may be accommodated in the display casing. The display casing may define an external shape of the display apparatus 1.

For example, the display casing may support the display panel 20. For example, the display casing may support the backlight unit 70. For example, the display casing may support the control assembly 50. For example, the display casing may support the power source assembly 60.

For example, the display apparatus 1 may include a top chassis 13. The top chassis 13 may include the top chassis 13 configured to support a front surface and a side surface of the display panel 20. For example, the top chassis 13 may be provided in the form of an approximately quadrangular frame. The top chassis 13 may be provided as a component of the display casing.

The top chassis 13 may define a bezel disposed to be directed toward a location disposed forward of the display apparatus 1. The top chassis 13 may support the front surface of the display panel 20. However, in case that the display apparatus 1 is a display apparatus with a very small bezel or a bezel-less type display apparatus, the top chassis 13 may be provided to support only the side surface of the display panel 20. Alternatively, in case that the bottom chassis 15 supports the side surface of the display panel 20, the display apparatus 1 may not include the top chassis 13.

For example, the display apparatus 1 may include the bottom chassis 15. The bottom chassis 15 may cover a rear side of the display panel 20. The bottom chassis 15 may be coupled to a rear side of the top chassis 13. The bottom chassis 15 may support various components of the display apparatus 1, such as the backlight unit 70, the control assembly 50, and the power source assembly 60. The bottom chassis 15 may be provided as a component of display casing.

The bottom chassis 15 may be provided in the form of an approximately flat plate. However, the present disclosure is not limited thereto. The bottom chassis 15 may include a material with a high thermal conductivity in order to dissipate heat, which is generated by the light source device 71, to the outside. For example, the bottom chassis 15 may include a metallic material, such as aluminum or SUS, or a plastic material such as ABS.

For example, the display apparatus 1 may include a middle mold 14. The middle mold 14 may be disposed between the top chassis 13 and the bottom chassis 15. For example, the middle mold 14 may support at least some components of the backlight unit 70. The middle mold 14 may be provided as a component of the display casing.

For example, the display apparatus 1 may include the rear cover 16. The rear cover 16 may be disposed rearward of the bottom chassis 15 and cover various types of components (e.g., the control assembly 50, the power source assembly 60, and the like) mounted rearward of the bottom chassis 15 and the bottom chassis 15. The rear cover 16 may be provided as a component of the display casing.

Unlike the configuration illustrated in FIGS. 2 and 3, the display apparatus 1 according to an embodiment of the present disclosure may not include some components among the top chassis 13, the middle mold 14, the bottom chassis 15, and the rear cover 16.

The components of the display apparatus 1, which has been described above with reference to FIGS. 2 and 3, are just examples for explaining the display apparatus according to the spirit of the present disclosure, and the spirit of the present disclosure is not limited thereto. The display apparatus according to the spirit of the present disclosure may be provided to include various components for performing a function of providing images by means of the screen.

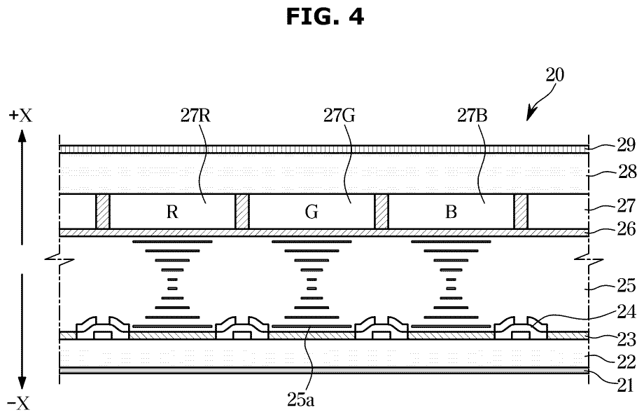

FIG. 4 is a cross-sectional view of the display panel according to an embodiment of the present disclosure.

With reference to FIG. 4, the display panel 20 included in the display apparatus 1 according to an embodiment of the present disclosure may be provided to block or transmit light emitted from the backlight unit 70. The image I may be formed at the front side of the display panel 20 by the operation of the display panel 20 that blocks or transmits the light emitted from the backlight unit 70.

The front surface of the display panel 20 may define the above-mentioned screen 12 of the display apparatus 1. A plurality of pixels P may be provided on the display panel 20. The plurality of pixels P provided on the display panel 20 may independently block or transmit the light emitted from the backlight unit 70, and the light transmitted by the plurality of pixels P may form the image I displayed on the screen 12.

For example, the display panel 20 may be configured as a liquid crystal display (LCD) panel.

For example, as illustrated in FIG. 4, the display panel 20 may include a first polarizing film 21, a first transparent substrate 22, a pixel electrode 23, a thin-film transistor 24, a liquid crystal layer 25, a common electrode 26, a color filter 27, a second transparent substrate 28, and a second polarizing film 29.

The first transparent substrate 22 and the second transparent substrate 28 may fix and/or support the pixel electrode 23, the thin-film transistor 24, the liquid crystal layer 25, the common electrode 26, and the color filter 27. The first and second transparent substrates 22 and 28 may be made of tempered glass or transparent resin.

The first polarizing film 21 and the second polarizing film 29 may be provided outside the first and second transparent substrates 22 and 28.

The first polarizing film 21 and the second polarizing film 29 may each transmit particular light and block the other light. For example, a polarization direction of the light transmitted by the first polarizing film 21 and a vibration direction of the light transmitted by the second polarizing film 29 may be orthogonal to each other. As a result, in general, the light cannot simultaneously pass through the first polarizing film 21 and the second polarizing film 29.

The color filter 27 may be provided inside the second transparent substrate 28.

For example, the color filter 27 may include a red filter 27R configured to transmit red light, a green filter 27G configured to transmit green light, and a blue filter 27B configured to transmit blue light. The red filter 27R, the green filter 27G, and the blue filter 27B may be disposed in parallel with one another. An area in which the color filter 27 is formed may correspond to the above-mentioned pixel P. An area in which the red filter 27R is formed may correspond to the red subpixel P_{R}, an area in which the green filter 27G is formed may correspond to the green subpixel P_{G}, and an area in which the blue filter 27B is formed may correspond to the blue subpixel P_{B}.

The pixel electrode 23 may be provided inside the first transparent substrate 22, and the common electrode 26 may be provided inside the second transparent substrate 28.

The pixel electrode 23 and the common electrode 26 may be made of an electrically conductive metallic material and generate an electric field for changing an arrangement of liquid crystal molecules 25a that constitute the liquid crystal layer 25 to be described below.

The pixel electrode 23 and the common electrode 26 may be made of a transparent material and transmit light entering from the outside. For example, the pixel electrode 23 and the common electrode 26 may be made of indium tin oxide (ITO), indium zinc oxide (IZO), Ag nano-wires, carbon nanotube (CNT), graphene, PEDOT (3,4-ethylenedioxythiophene), or the like.

The thin-film transistor (TFT) 24 may be provided inside the first transparent substrate 22.

The thin-film transistor 24 may transmit or block an electric current flowing along the pixel electrode 23. For example, an electric field may be generated or removed between the pixel electrode 23 and the common electrode 26 as the thin-film transistor 24 is turned on (closed) or turned off (opened).

The thin-film transistor 24 may be made of polysilicon and formed by semiconductor processes such as lithography, deposition, and ion implantation processes.

The liquid crystal layer 25 may be formed between the pixel electrode 23 and the common electrode 26. The liquid crystal layer 25 may be filled with the liquid crystal molecules 25a.

Liquid crystals are in a state between solid (crystalline) and liquid. Most liquid crystal materials are organic compounds with long, thin rod-shaped molecules. The arrangement of molecules is irregular in some directions but may have a regular crystalline structure in other directions. As a result, liquid crystals have both the fluidity of liquids and the optical anisotropy of crystals (solids).

In addition, liquid crystals may exhibit optical properties depending on changes in electric fields. For example, the direction of the molecular arrangement, which constitutes the liquid crystal, may change in response to changes in electric fields. When the electric field is generated on the liquid crystal layer 25, the liquid crystal molecules 25a in the liquid crystal layer 25 may be disposed in the direction of the electric field. When no electric field is formed on the liquid crystal layer 25, the liquid crystal molecules 25a may be disposed irregularly or disposed along an alignment film (not illustrated). As a result, the optical properties of the liquid crystal layer 25 may vary depending on the presence or absence of the electric field passing through the liquid crystal layer 25.

The structure of the display panel 20, which has been described above with reference to FIG. 4, is just an example of the structure that the display panel of the display apparatus according to the spirit of the present disclosure may have. The spirit of the present disclosure is not limited thereto.

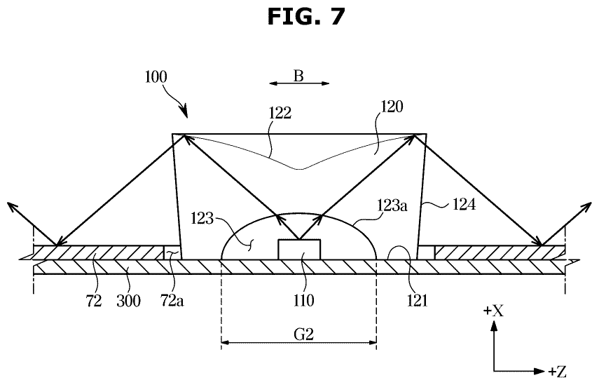

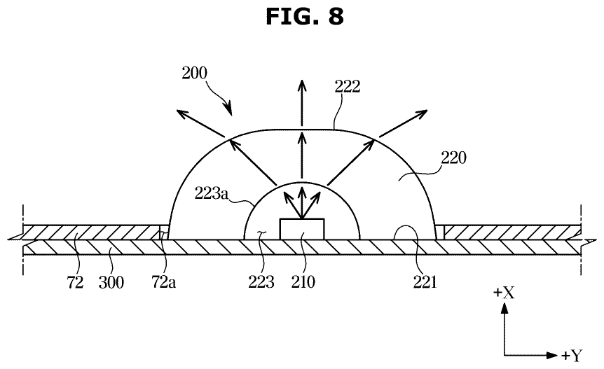

FIG. 5 is a perspective view of the light source device according to an embodiment of the present disclosure. FIG. 6 is a cross-sectional view schematically illustrating the reflective sheet and a first light source of the light source device according to an embodiment of the present disclosure. FIG. 7 is a cross-sectional view schematically illustrating the reflective sheet and the first light source of the light source device according to an embodiment of the present disclosure. FIG. 8 is a cross-sectional view schematically illustrating the reflective sheet and a second light source of the light source device according to an embodiment of the present disclosure.

The display apparatus 1 according to an embodiment of the present disclosure may include the backlight unit 70. The backlight unit 70 may include the light source device 71. The backlight unit 70 may include the reflective sheet 72. For example, at least a part of the light source device 71 may be positioned forward of the reflective sheet 72.

The light source device 71 may include the substrate 300. The substrate 300 may be provided such that the light sources 100 and 200 to be described below are mounted on the substrate 300. The substrate 300 may be provided to supply electric power to the light sources 100 and 200. The substrate 300 may be provided to fix and/or support the light sources 100 and 200.

For example, the substrate 300 may include a printed circuit board (PCB). A circuit pattern (not illustrated) or the like for transmitting driving power and signals to the light sources 100 and 200 may be formed on the substrate 300. A connector (not illustrated) configured to be connected to an external circuit may be mounted on the substrate 300.

The light source device 71 may include a plurality of first light sources 100. The plurality of first light sources 100 may each be provided to emit light. The plurality of first light sources 100 may each be provided to provide light to the display panel 20. The first light source 100 may adopt an element capable of emitting monochromatic light (light with a particular wavelength, e.g., blue light) or white light (e.g., light made by mixing red light, green light, and blue light) in various directions when electric power is supplied.

The plurality of first light sources 100 may be mounted on the substrate 300. The plurality of first light sources 100 may be provided on the front surface of the substrate 300. In this case, the front surface of the substrate 300 may be referred to as an surface of the substrate 300 directed toward the display panel 20. That is, the plurality of first light sources 100 may each be mounted on the substrate 300 so as to be directed forward and provided to emit light.

The plurality of first light sources 100 may each include a first light-emitting diode (LED) 110.

The first light-emitting diode 110 may include a P-type semiconductor and an N-type semiconductor for emitting light by recombining positive holes and electrons. In addition, a pair of electrodes may be provided on the first light-emitting diode 110 to supply positive holes and electrons to the P-type semiconductor and the N-type semiconductor.

The first light-emitting diode 110 may be configured to convert electrical energy into optical energy. The first light-emitting diode 110 may emit light with maximum intensity in a predetermined wavelength on the basis of the supplied electric power.

For example, a multilayer reflection structure, in which a plurality of insulation films having different refractive indexes are alternately stacked, may be provided on the front surface of the first light-emitting diode 110. For example, the multilayer reflection structure may be configured as a distributed Bragg reflector (DBR).

For example, the first light-emitting diode 110 may be attached directly to the substrate 300 in a chip-on-board (COB) manner. In other words, the first light sources 100 may each include the first light-emitting diode 110 in which a light-emitting diode chip or a light-emitting diode die is attached directly to the substrate 300 without separate packaging.

The plurality of first light sources 100 may each include an anisotropic reflection lens 120. For example, the anisotropic reflection lens 120 may include a recessed shape.

The anisotropic reflection lens 120 may be provided to cover the first light-emitting diode 110. The anisotropic reflection lens 120 may protect the first light-emitting diode 110. The anisotropic reflection lens 120 may prevent or suppress damage to the first light-emitting diode 110.

The anisotropic reflection lens 120 may reflect the light emitted from the first light-emitting diode 110. Specifically, a reflective surface 122 (see FIGS. 6 and 7) of the anisotropic reflection lens 120 may reflect the light emitted from the first light-emitting diode 110. In this case, the configuration in which the anisotropic reflection lens 120 reflects the light emitted from the first light-emitting diode 110 may include not only a configuration in which the anisotropic reflection lens 120 reflects 100% of the light emitted from the first light-emitting diode 110 but also a configuration in which the anisotropic reflection lens 120 reflects most of the light emitted from the first light-emitting diode 110.

The anisotropic reflection lens 120 may diffuse the light emitted from the first light-emitting diode 110 by reflecting the light emitted from the first light-emitting diode 110. For example, the anisotropic reflection lens 120 may guide the light emitted from the first light-emitting diode 110 in an approximate first direction A and/or an approximate second direction B. For example, the anisotropic reflection lens 120 may allow the light emitted from the first light-emitting diode 110 to propagate along an approximate Y-Z plane.

The anisotropic reflection lens 120 may have an anisotropic light distribution structure. The anisotropic reflection lens 120 may be provided to send the light farther in a particular direction. A route for the light reflected by the anisotropic reflection lens 120 may vary depending on the directionality of the light entering the anisotropic reflection lens 120. For example, the anisotropic reflection lens 120 may send the light, which is emitted from the first light-emitting diode 110, farther in the second direction B than in the first direction A. This configuration will be described in detail below.

The light source device 71 may include at least one second light source 200. The second light source 200 may be provided to emit light. The second light source 200 may be provided to provide light to the display panel 20. The second light source 200 may adopt an element capable of emitting monochromatic light (light with a particular wavelength, e.g., blue light) or white light (e.g., light made by mixing red light, green light, and blue light) in various directions when electric power is supplied.

The second light source 200 may be mounted on the substrate 300. The second light source 200 may be provided on the front surface of the substrate 300. In this case, the front surface of the substrate 300 may be referred to as an surface of the substrate 300 directed toward the display panel 20. That is, the second light source 200 may be mounted on the substrate 300 so as to be directed forward and provided to emit light.

The second light source 200 may include a second light-emitting diode (LED) 210.

The second light-emitting diode 210 may include a P-type semiconductor and an N-type semiconductor for emitting light by recombining positive holes and electrons. In addition, a pair of electrodes may be provided on the second light-emitting diode 210 to supply positive holes and electrons to the P-type semiconductor and the N-type semiconductor.

The second light-emitting diode 210 may be configured to convert electrical energy into optical energy. The second light-emitting diode 210 may emit light with maximum intensity in a predetermined wavelength on the basis of the supplied electric power.

For example, a multilayer reflection structure, in which a plurality of insulation films having different refractive indexes are alternately stacked, may be provided on the front surface of the second light-emitting diode 210. For example, the multilayer reflection structure may be configured as a distributed Bragg reflector (DBR).

For example, the second light-emitting diode 210 may be attached directly to the substrate 300 in a chip-on-board (COB) manner. In other words, the second light source 200 may include the second light-emitting diode 210 in which a light-emitting diode chip or a light-emitting diode die is attached directly to the substrate 300 without separate packaging.

The second light source 200 may include a refractive lens 220. For example, the refractive lens 220 may include a dome shape.

The refractive lens 220 may be provided to cover the second light-emitting diode 210. The refractive lens 220 may protect the second light-emitting diode 210. The refractive lens 220 may prevent or suppress damage to the second light-emitting diode 210.

The refractive lens 220 may refract the light emitted from the second light-emitting diode 210. In this case, the configuration in which the refractive lens 220 refracts the light emitted from the second light-emitting diode 210 may include not only a configuration in which the refractive lens 220 refracts 100% of the light emitted from the second light-emitting diode 210 but also a configuration in which the refractive lens 220 refracts most of the light emitted from the second light-emitting diode 210.

For example, the refractive lens 220 cannot send light relatively farther in comparison with the anisotropic reflection lens 120. However, the luminance of a portion disposed immediately above the refractive lens 220 may be relatively higher than the luminance of a portion disposed immediately above the anisotropic reflection lens 120. For example, the refractive lens 220 may guide the light, which is emitted from the second light-emitting diode 210, in an approximate forward direction (+X direction) and a direction approximate to the forward direction. The refractive lens 220 may be disposed between the anisotropic reflection lenses 120 and compensate for the luminance. The refractive lens 220 may be disposed at a point with relatively low luminance. This configuration will be described in detail below.

The present disclosure has been described in which the first light source 100 includes the anisotropic reflection lens 120 with a recessed shape. However, the present disclosure is not limited thereto. The first light source 100 may include a first lens with various types and/or shapes capable of reflecting light. Likewise, the present disclosure has been described in which the second light source 200 includes the refractive lens 220 with a dome shape. However, the present disclosure is not limited thereto. The second light source 200 may include a second lens with various types and/or shapes capable of refracting light. The first lens and the second lens may be substituted for the anisotropic reflection lens 120 and the refractive lens 220. The anisotropic reflection lens 120 and the refractive lens 220 may be respectively referred to as a first lens 120 and a second lens 220.

Next, a shape of the anisotropic reflection lens 120 of the first light source 100 and an optical path of the first light source 100 will be described with reference to FIGS. 6 and 7. However, FIGS. 6 and 7 are provided for illustrative purposes only, and scales of some components may be exaggerated for convenience of description.

The first light source 100 may include the first light-emitting diode 110, and the anisotropic reflection lens 120 provided to cover the first light-emitting diode 110.

The anisotropic reflection lens 120 may include a bottom portion 121 seated on the substrate 300. The bottom portion 121 may be attached to the substrate 300. For example, an outermost periphery of the bottom portion 121 may have various shapes such as a circular shape, an elliptical shape, or a polygonal shape.

The anisotropic reflection lens 120 may include the reflective surface 122 provided to be opposite to the bottom portion 121. The reflective surface 122 may be disposed to be directed toward the display panel 20. The reflective surface 122 may be disposed to be directed toward the optical member 73 and/or 74. The reflective surface 122 may be provided to reflect light emitted from the first light-emitting diode 110. The reflective surface 122 may have a shape recessed inward. The reflective surface 122 may have a shape recessed rearward (−X direction). The reflective surface 122 may have a concave shape. For example, the reflective surface 122 may include a shape inclined downward toward a center of the anisotropic reflection lens 120.

The anisotropic reflection lens 120 may include a side surface portion 124 provided to connect the bottom portion 121 and the reflective surface 122. The side surface portion 124 may extend in an approximate forward/rearward direction (X direction). The side surface portion 124 may have an approximate column shape.

The anisotropic reflection lens 120 may include a groove portion 123. The groove portion 123 may be provided to accommodate the first light-emitting diode 110. When the anisotropic reflection lens 120 covers the first light-emitting diode 110, the first light-emitting diode 110 may be disposed in the groove portion 123. The groove portion 123 may be recessed from the bottom portion 121. The groove portion 123 may have a shape recessed forward (+X direction) from the bottom portion 121.

The anisotropic reflection lens 120 may include an incident surface 123a. The groove portion 123 may be formed in the anisotropic reflection lens 120, such that the incident surface 123a may be formed. The incident surface 123a may be provided to define the groove portion 123. The incident surface 123a may be provided to surround the first light-emitting diode 110. The light emitted from the first light-emitting diode 110 may be refracted while passing through the incident surface 123a.

The anisotropic reflection lens 120 may send the light farther in a predetermined direction. To this end, a cross-sectional shape of the groove portion 123 of the anisotropic reflection lens 120 may not be uniform.

For example, a first size (see FIG. 6) of the groove portion 123 in the first direction A and a second size (see FIG. 7) of the groove portion 123 in the second direction B may be different from each other. In this case, the size of the groove portion 123 may refer to a maximum size based on a cross-section of the groove portion 123.

For example, a first length G1 (see FIG. 6) of the groove portion 123 in the first direction A may be shorter than a second length G2 (see FIG. 7) of the groove portion 123 in the second direction B. The second length G2 (see FIG. 7) of the groove portion 123 in the second direction B may be longer than the first length G1 (see FIG. 6) of the groove portion 123 in the first direction A. In this case, the length of the groove portion 123 may refer to a maximum length based on the cross-section of the groove portion 123.

Therefore, the light emitted from the first light-emitting diode 110 may be guided farther in the second direction B than in the first direction A by the groove portion 123 of the anisotropic reflection lens 120. That is, the anisotropic reflection lens 120 may send the light, which is emitted from the first light-emitting diode 110, farther in the second direction B than in the first direction A.

For example, with reference to FIG. 6, in case that the size (or length) of the groove portion 123 is small (short), a distance between the first light-emitting diode 110 and the incident surface 123a may be relatively short. Therefore, a ratio between the light passing through the incident surface 123a and reflected by a central portion of the reflective surface 122 and the light passing through the incident surface 123a and reflected by a portion adjacent to the central portion of the reflective surface 122 may be relatively high. The light reflected from the central portion of the reflective surface 122 and the portion adjacent to the central portion of the reflective surface 122 may not propagate relatively farther in comparison with the light reflected by an outer peripheral portion of the reflective surface 122 and a portion adjacent to the outer peripheral portion of the reflective surface 122.

For example, with reference to FIG. 7, in case that the size (or length) of the groove portion 123 is large (long), the distance between the first light-emitting diode 110 and the incident surface 123a may be relatively long. Therefore, a ratio between the light passing through the incident surface 123a and reflected by the outer peripheral portion of the reflective surface 122 and the light passing through the incident surface 123a and reflected by the portion adjacent to the outer peripheral portion of the reflective surface 122 may be relatively high. The light reflected from the outer peripheral portion of the reflective surface 122 and the portion adjacent to the outer peripheral portion of the reflective surface 122 may propagate relatively farther in comparison with the light reflected by the central portion of the reflective surface 122 and the portion adjacent to the central portion of the reflective surface 122.

Next, a shape of the refractive lens 220 of the second light source 200 and an optical path of the second light source 200 will be described with reference to FIG. 8. However, FIG. 8 is provided for illustrative purposes only, and scales of some components may be exaggerated for convenience of description.

The second light source 200 may include the second light-emitting diode 210, and the refractive lens 220 provided to cover the second light-emitting diode 210.

The refractive lens 220 may include a bottom portion 221 seated on the substrate 300. The bottom portion 221 may be attached to the substrate 300. For example, an outermost periphery of the bottom portion 221 may have various shapes such as a circular shape, an elliptical shape, or a polygonal shape.

The refractive lens 220 may include an emergent surface 222. The emergent surface 222 may be disposed to be directed toward the display panel 20. The emergent surface 222 may be disposed to be directed toward the optical member 73 and/or 74. The light emitted from the second light-emitting diode 210 may propagate from the refractive lens 220 through the emergent surface 222. For example, the light may be refracted by the emergent surface 222. The emergent surface 222 may include a dome shape. The emergent surface 222 may have a convex shape. For example, the emergent surface 222 may include a shape inclined upward toward a center of the refractive lens 220.

The refractive lens 220 may include a groove portion 223. The groove portion 223 may be provided to accommodate the second light-emitting diode 210. When the refractive lens 220 covers the second light-emitting diode 210, the second light-emitting diode 210 may be disposed in the groove portion 223. The groove portion 223 may be recessed from the bottom portion 221. The groove portion 223 may have a shape recessed forward (+X direction) from the bottom portion 221.

The refractive lens 220 may include an incident surface 223a. The groove portion 223 is formed in the refractive lens 220, such that the incident surface 223a may be formed. The incident surface 223a may be provided to define the groove portion 223. The incident surface 223a may be provided to surround the second light-emitting diode 210. The light emitted from the second light-emitting diode 210 may be refracted while passing through the incident surface 223a.

The refractive lens 220 may guide the light in an approximate forward direction (+X direction) and a direction approximate to the forward direction. The light (see FIG. 8) emitted from the second light source 200 may be directed relatively forward (+X direction) in comparison with the light (see FIGS. 6 and 7) emitted from the first light source 100. That is, the luminance of the portion disposed immediately above the refractive lens 220 may be relatively higher than the luminance of the portion disposed immediately above the anisotropic reflection lens 120. As a result, the luminance of a portion disposed immediately above the second light source 200 may be relatively higher than the luminance of a portion disposed immediately above the first light source 100.

For example, with reference to FIG. 8, the light emitted from the second light-emitting diode 210 may be refracted by the incident surface 223a. The light refracted by the incident surface 223a may be refracted by the emergent surface 222. For example, a refractive index of the refractive lens 220 may vary depending on a material, a medium, or the like of the refractive lens 220.

FIG. 9 is a front view schematically illustrating an example of the display apparatus according to an embodiment of the present disclosure. However, the present disclosure is not limited to the configuration illustrated in FIG. 9. The display apparatus may further include an additional light source device in addition to the light source device 71 illustrated in FIG. 9. In this case, the additional light source device may be substantially identical to the light source device 71 or different from the light source device 71.

With reference to FIG. 9, the light source device 71 may include the substrate 300, the plurality of first light sources 100 mounted on the substrate 300, and at least one second light source 200 mounted on the substrate 300.

For example, the substrate 300 may include a shape elongated in a direction. The substrate 300 may include a bar shape extending in the first direction A. That is, the substrate 300 may have a length longer in the first direction A than in the second direction B.

The second light source 200 may be disposed between the two adjacent light sources 100 among the plurality of first light sources 100. The second light source 200 may be disposed between the two adjacent first light sources 100 among the plurality of first light sources 100. The drawings illustrate that one second light source 200 is disposed between the two first light sources 100. However, the plurality of second light sources 200 may be disposed between the two first light sources 100.

For example, the plurality of first light sources 100 may be disposed to be spaced apart from one another in the first direction A. Among the plurality of first light sources 100, a first distance D1 in the first direction A between any one first light source and another first light source adjacent to one first light source may be longer than a second distance D2 in the first direction A between the second light source 200 and the first light source adjacent to the second light source 200. In this case, the distance may refer to a distance between a center of one component and a center of another component. This meaning may also be applied to a distance mentioned below.

For example, the plurality of first light sources 100 may be disposed to be spaced apart from one another by the predetermined first distance D1 in the first direction A. In this case, the second light source 200 may be disposed between the two first light sources 100. Therefore, the first distance D1 may be longer than the second distance D2.

However, unlike the above-mentioned example, the plurality of first light sources 100 may not be spaced apart from one another by a predetermined distance in the first direction A. The plurality of first light sources 100 may be spaced apart from one another at non-uniform intervals. In this case, a minimum distance between the first light sources 100 in the first direction A may be longer than a maximum distance between the first light source 100 and the second light source 200 in the first direction A.

For example, the second light source 200 may be disposed at a center between the two adjacent first light sources 100 among the plurality of first light sources 100. In this case, the second distance D2 may be approximately ½ times the first distance D1.

For example, the second light source 200 may be disposed to correspond to a center C of the display panel 20. That is, the center of the second light source 200 and the center C of the display panel 20 may be approximately consistent with each other. The second light source 200 may be disposed to correspond to a ½ point (e.g., halfway point) of the display panel 20 in the first direction A. The second light source 200 may be disposed to correspond to a ½ point of the display panel 20 in the second direction B.

For example, although not illustrated in FIG. 9, the second light source 200 may be disposed to correspond to a point spaced apart from a short side 20c or 20d of the display panel 20 by a ⅙ length of the display panel 20 in the first direction A. The second light source 200 may be disposed to correspond to a point spaced apart from a long side 20a or 20b of the display panel 20 by a ⅙ length of the display panel 20 in the second direction B. The purpose of the arrangement of the second light source 200 will be described below.

A distance (e.g., ½*L2) in the second direction B between the plurality of first light sources 100 and the long side 20a or 20b of the display panel 20 may be longer than a distance (e.g., the first distance D) in the first direction A between the plurality of first light sources 100. Therefore, in order to ensure the uniformity of the screen of the display apparatus, i.e., send the light farther in the second direction B than in the first direction A, the plurality of first light sources 100 may each include the anisotropic reflection lens 120. As described above, the anisotropic reflection lens 120 may guide the light farther in the second direction B than in the first direction A. However, in case that the light source device 71 has only the anisotropic reflection lens 120, the luminance of a portion disposed immediately above the light source device 71 may relatively decrease. In order to cope with the decrease in luminance, the light source device 71 may include at least one second light source 200 to compensate for the luminance. The second light source 200 may include the refractive lens 220, and the refractive lens 220 may guide the light in a direction (e.g., forward direction (+X direction)) toward the display panel 20 and a direction approximate to the direction toward the display panel 20. The second light source 200 may be provided to improve luminance at a particular point. The second light source 200 may be disposed at an appropriate point at which the luminance needs to be compensated. The second light source 200 may be provided at various positions in accordance with various factors. For example, the second light source 200 may be disposed to correspond to the central portion of the display apparatus and/or a portion for measuring uniformity of the display apparatus. The arrangement of the second light source 200 may be determined on the basis of the purpose of the above-mentioned description. In addition, the purpose of the above-mentioned description may, of course, be applied to the embodiment(s) to be described below.

FIG. 10 is a front view schematically illustrating an example of the display apparatus according to an embodiment of the present disclosure. However, the present disclosure is not limited to the configuration illustrated in FIG. 10. The display apparatus may not include some of the plurality of light source devices 71 illustrated in FIG. 10. Alternatively, the display apparatus may further include an additional light source device in addition to the plurality of light source devices 71 illustrated in FIG. 10. In this case, the additional light source device may be substantially identical to the light source device 71 or different from the light source device 71.

The description identical to the description of the above-mentioned embodiment(s) may be omitted. The same reference numerals will be assigned to the components substantially identical to the above-mentioned components, and a detailed description thereof may be omitted.

With reference to FIG. 10, the display apparatus according to an embodiment of the present disclosure may include the plurality of light source devices 71. For example, the display apparatus may include a first light source device 71a, a second light source device 71b, and a third light source device 71c. The first light source device 71a, the second light source device 71b, and the third light source device 71c are distinguished for convenience of description. The ordinal numbers “first,” “second,” and “third” do not limit the corresponding components. The drawings illustrate that the display apparatus includes the three light source devices 71a, 71b, and 71c. However, the present disclosure is not limited thereto. For example, the display apparatus according to an embodiment of the present disclosure may include two light source devices 71. For example, the display apparatus according to an embodiment of the present disclosure may include four or more light source devices 71.

The plurality of light source devices 71 may be provided to have substantially the same configuration, except for the arrangement thereof. The light source devices 71a, 71b, and 71c may each include the substrate 300, the plurality of first light sources 100 mounted on the substrate 300, and at least one second light source 200 mounted on the substrate 300.

For example, the plurality of light source devices 71 may be disposed to be spaced apart from one another in the second direction B. For example, the plurality of light source devices 71 may be disposed to be spaced apart from one another at predetermined intervals in the second direction B. The second light source device 71b may be disposed above the first light source device 71a, and the third light source device 71c may be disposed below the first light source device 71a.

For example, the plurality of substrates 300 may each include a shape extending in a direction. For example, the substrates 300 may each include a bar shape extending in the first direction A. That is, the substrates 300 may each have a length longer in the first direction A than in the second direction B. In addition, the plurality of substrates 300 may be disposed to be spaced apart from one another in the second direction B.

For example, the second light source 200 of each of the light source devices 71 may be disposed to correspond to a ½ point of the display panel 20 in the first direction A. A center of each of the second light source 200 may be approximately consistent with a ½ point of the display panel 20 in the first direction A.

For example, the second light source 200 of any one of the plurality of light source devices 71 may be disposed to correspond to a ½ point of the display panel 20 in the second direction B. The second light source 200 of the first light source device 71a may be disposed to correspond to a ½ point of the display panel 20 in the second direction B. The second light source 200 of the first light source device 71a may be disposed to correspond to the center C of the display panel 20.

For example, the second light source 200 of any one of the plurality of light source devices 71 may be disposed to correspond to a point spaced apart from the long side 20a or 20b of the display panel 20 by a ⅙ length of the display panel 20 in the second direction B. The second light source 200 of the second light source device 71b may be disposed to correspond to a point spaced apart from the first long side 20a of the display panel 20 by a ⅙ length of the display panel 20 in the second direction B. The second light source 200 of the third light source device 71c may be disposed to correspond to a point spaced apart from the second long side 20b of the display panel 20 by a ⅙ length of the display panel 20 in the second direction B.

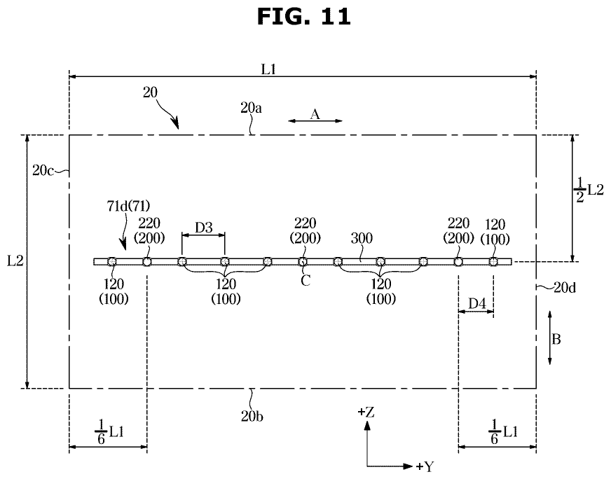

FIG. 11 is a front view schematically illustrating an example of the display apparatus according to an embodiment of the present disclosure. However, the present disclosure is not limited to the configuration illustrated in FIG. 11. The display apparatus may further include an additional light source device in addition to the light source device 71 illustrated in FIG. 11. In this case, the additional light source device may be substantially identical to the light source device 71 or different from the light source device 71.

The description identical to the description of the above-mentioned embodiment(s) may be omitted. The same reference numerals will be assigned to the components substantially identical to the above-mentioned components, and a detailed description thereof may be omitted.

With reference to FIG. 11, the light source device 71 according to an embodiment of the present disclosure may include the substrate 300, the plurality of first light sources 100 mounted on the substrate 300, and the plurality of second light sources 200 mounted on the substrate 300.

For example, the substrate 300 may include a shape elongated in a direction. The substrate 300 may include a bar shape extending in the first direction A. That is, the substrate 300 may have a length longer in the first direction A than in the second direction B.

For example, the plurality of first light sources 100 may be disposed to be spaced apart from one another in the first direction A. For example, the plurality of first light sources 100 may be disposed to be spaced apart from one another at non-uniform intervals in the first direction A. In this case, a minimum distance D3 between the first light sources 100 in the first direction A may be longer than a maximum distance D4 between the first light source 100 and the second light source 200 in the first direction A.

However, unlike the above-mentioned example, the plurality of first light sources 100 may be disposed to be spaced apart from one another by predetermined distances in the first direction A.

For example, the plurality of second light sources 200 may each be disposed between the two adjacent first light sources 100. For example, the plurality of second light sources 200 may each be disposed at a center between the two adjacent first light sources 100.

For example, any one of the plurality of second light sources 200 may be disposed to correspond to a point spaced apart from the short side 20c or 20d of the display panel 20 by a ⅙ length of the display panel 20 in the first direction A.

For example, any one of the plurality of second light sources 200 may be disposed to correspond to a ½ point of the display panel 20 in the first direction A. Any one of the plurality of second light sources 200 may be disposed to correspond to a ½ point of the display panel 20 in the second direction B. Any one of the plurality of second light sources 200 may be disposed to correspond to a center C of the display panel 20.

For example, any one of the plurality of second light sources 200 may be disposed to correspond to a ½ point of the display panel 20 in the first direction A. Another of the plurality of second light sources 200 may be disposed to correspond to a point spaced apart from the first short side 20c of the display panel 20 by a ⅙ length of the display panel 20 in the first direction A. Still another of the plurality of second light sources 200 may be disposed to correspond to a point spaced apart from the second short side 20d of the display panel 20 by a ⅙ length of the display panel 20 in the first direction A. The plurality of second light sources 200 may be disposed to correspond to a ½ point of the display panel 20 in the second direction B.

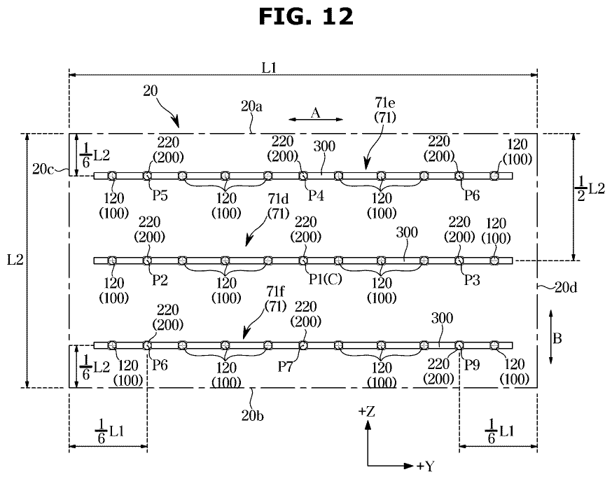

FIG. 12 is a front view schematically illustrating an example of the display apparatus according to an embodiment of the present disclosure. However, the present disclosure is not limited to the configuration illustrated in FIG. 12. The display apparatus may not include some of the plurality of light source devices 71 illustrated in FIG. 12. Alternatively, the display apparatus may further include an additional light source device in addition to the plurality of light source devices 71 illustrated in FIG. 12. In this case, the additional light source device may be substantially identical to the light source device 71 or different from the light source device 71.

The description identical to the description of the above-mentioned embodiment(s) may be omitted. The same reference numerals will be assigned to the components substantially identical to the above-mentioned components, and a detailed description thereof may be omitted.

With reference to FIG. 12, the display apparatus according to an embodiment of the present disclosure may include the plurality of light source devices 71. For example, the display apparatus may include a fourth light source device 71d, a fifth light source device 71e, and a sixth the light source device 71f. The fourth light source device 71d, the fifth light source device 71e, and the sixth light source device 71f are distinguished for convenience of description. The ordinal numbers “fourth,” “fifth,” and “sixth” do not limit the corresponding components. The drawings illustrate that the display apparatus includes the three light source devices. However, the present disclosure is not limited thereto. For example, the display apparatus according to an embodiment of the present disclosure may include two light source devices 71. For example, the display apparatus according to an embodiment of the present disclosure may include four or more light source devices 71.

The plurality of light source devices 71 may be provided to have substantially the same configuration, except for the arrangement thereof. The light source devices 71d, 71e, and 71f may each include the substrate 300, the plurality of first light sources 100 mounted on the substrate 300, and the plurality of second light source 200 mounted on the substrate 300.

For example, the plurality of light source devices 71 may be disposed to be spaced apart from one another in the second direction B. The plurality of light source devices 71 may be disposed to be spaced apart from one another at predetermined intervals in the second direction B. The fifth light source device 71e may be disposed above the fourth light source device 71d, and the sixth the light source device 71f may be disposed below the fourth light source device 71d.

For example, the plurality of substrates 300 may each include a shape extending in a direction. For example, the substrates 300 may each include a bar shape extending in the first direction A. That is, the substrates 300 may each have a length longer in the first direction A than in the second direction B. In addition, the plurality of substrates 300 may be disposed to be spaced apart from one another in the second direction B.

For example, the plurality of second light sources 200 of the fourth light source device 71d may be disposed to correspond to points spaced apart from a long side 20a or 20b of the display panel 20 by a ½ length of the display panel 20 in the second direction B (see P1, P2, and P3 in FIG. 12). Any one of the plurality of second light sources 200 of the fourth light source device 71d may be disposed to correspond to a ½ point of the display panel 20 in the first direction A (see P1 in FIG. 12). Another of the plurality of second light sources of the fourth light source device 71d may be disposed to correspond to a point spaced apart from the first short side 20c of the display panel 20 by a ⅙ length of the display panel 20 in the first direction A (see P2 in FIG. 12). Still another of the plurality of second light sources of the fourth light source device 71d may be disposed to correspond to a point spaced apart from the second short side 20d of the display panel 20 by a ⅙ length of the display panel 20 in the first direction A (see P3 in FIG. 12).

For example, the plurality of second light sources 200 of the fifth light source device 71e may be disposed to correspond to points spaced apart from the first long side 20a by a ⅙ length of the display panel in the second direction B (see P4, P5, and P6 in FIG. 12). Any one of the plurality of second light sources 200 of the fifth light source device 71e may be disposed to correspond to a ½ point of the display panel 20 in the first direction A (see P4 in FIG. 12). Another of the plurality of second light sources of the fifth light source device 71e may be disposed to correspond to a point spaced apart from the first short side 20c of the display panel 20 by a ⅙ length of the display panel 20 in the first direction A (see P5 in FIG. 12). Still another of the plurality of second light sources of the fifth light source device 71e may be disposed to correspond to a point spaced apart from the second short side 20d of the display panel 20 by a ⅙ length of the display panel 20 in the first direction A (see P6 in FIG. 12).

For example, the plurality of second light sources 200 of the sixth light source device 71f may be disposed to correspond to points spaced apart from the second long side 20b by a ⅙ length of the display panel in the second direction B (see P7, P8, and P9 in FIG. 12). Any one of the plurality of second light sources 200 of the sixth light source device 71f may be disposed to correspond to a ½ point of the display panel 20 in the first direction A (see P7 in FIG. 12). Another of the plurality of second light sources of the sixth light source device 71f may be disposed to correspond to a point spaced apart from the first short side 20c of the display panel 20 by a ⅙ length of the display panel 20 in the first direction A (see P8 in FIG. 12). Still another of the plurality of second light sources of the sixth light source device 71f may be disposed to correspond to a point spaced apart from the second short side 20d of the display panel 20 by a ⅙ length of the display panel 20 in the first direction A (see P9 in FIG. 12).

In general, in order to evaluate the uniformity of the display apparatus, the screen of the display apparatus may be divided into nine areas, and the brightness at center points of the areas may be measured and compared (9-point uniformity). For example, assuming that a horizontal length of the display panel 20 is L1 and a vertical length of the display panel is L2, the nine measurement points are P1 (½*L1, ½*L2), P2 (⅙*L1, ½*L2), P3 (⅚*L1, ½*L2), P4 (½*L1, ⅙*L2), P5 (⅙*L1, ⅙*L2), P6 (⅚*L1, ⅙*L2), P7 (½*L1, ⅚*L2), P8 (⅙*L1, ⅚*L2), and P9 (⅚*L1, ⅚*L2) based on a left upper corner of the display panel 20. In consideration of this configuration, according to an embodiment of the present disclosure, the second light source 200 may be provided to be disposed on at least one of the above-mentioned nine measurement points. The second light source 200 may compensate for the luminance at the above-mentioned nine measurement points. Therefore, the luminous efficiency and uniformity of the display apparatus may be improved.

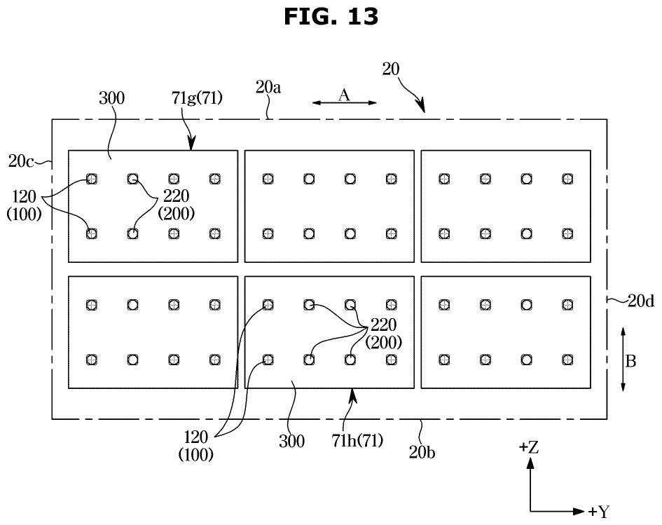

FIG. 13 is a front view schematically illustrating an example of the display apparatus according to an embodiment of the present disclosure. However, the present disclosure is not limited to the configuration illustrated in FIG. 13. The display apparatus may not include some of the plurality of light source devices 71 illustrated in FIG. 13. Alternatively, the display apparatus may further include an additional light source device in addition to the plurality of light source devices 71 illustrated in FIG. 13. In this case, the additional light source device may be substantially identical to the light source device 71 or different from the light source device 71.

The description identical to the description of the above-mentioned embodiment(s) may be omitted. The same reference numerals will be assigned to the components substantially identical to the above-mentioned components, and a detailed description thereof may be omitted.

With reference to FIG. 13, the display apparatus according to an embodiment of the present disclosure may include the plurality of light source devices 71. For example, the display apparatus may include substantially identical light source devices or include different light source devices 71g and 71h. For example, the display apparatus may include a seventh light source device 71g. For example, the display apparatus may include an eighth light source device 71h. However, the display apparatus according to an embodiment of the present disclosure may include one light source device 71.

For example, the plurality of light source devices 71 may be arranged in a matrix shape with M×N (M and N are natural numbers). FIG. 13 illustrates that six light source devices 71 are arranged in a 2×3 matrix shape. However, the present disclosure is not limited to the configuration illustrated in FIG. 13. The plurality of light source devices may, of course, be disposed in various patterns.

For example, the plurality of light source devices 71 may each include the substrate 300, the plurality of first light sources 100 mounted on the substrate 300, and at least one second light source 200 mounted on the substrate 300. For example, the light sources 100 and 200 may be arranged in a matrix shape.

For example, the plurality of substrates 300 may each include a plate shape having a plane in the first direction A and the second direction B. The plurality of substrates 300 may each include a plate shape having a Y-Z plane.

For example, the plurality of second light sources 200 may be disposed to correspond to a central portion of the display apparatus and a portion adjacent to the central portion.

For example, the plurality of second light sources 200 may be disposed to correspond to a portion for measuring uniformity of the display apparatus and a portion adjacent to the portion for measuring uniformity. For example, the plurality of second light sources 200 may be disposed to correspond to nine measurement points (see P1 to P9 in FIG. 12) and a portion adjacent to the nine measurement points.

The display apparatus according to an embodiment of the present disclosure is not limited to the configuration illustrated in FIGS. 10 to 13. Although not illustrated in the drawings, a combination of the light source devices 71a, 71b, 71c, 71d, 71e, 71f, 71g and/or 71f may be implemented.

The display apparatus according to an embodiment of the present disclosure may include the display panel, and the light source device provided to provide light to the display panel. The light source device may include the substrate, the plurality of first light sources mounted on the substrate, and the second light source mounted on the substrate and disposed between the two adjacent first light sources among the plurality of first light sources. The plurality of first light sources may each include the first light-emitting diode, and the anisotropic reflection lens provided to cover the first light-emitting diode. The second light source may include the second light-emitting diode, and the refractive lens provided to cover the second light-emitting diode.

The display panel may include the pair of long sides extending in the first direction, and the pair of short sides extending in the second direction. The plurality of first light sources may be disposed to be spaced apart from one another in the first direction. Among the plurality of first light sources, the first distance in the first direction between any one first light source and another first light source adjacent to one first light source may be longer than the second distance in the first direction between the second light source and the first light source adjacent to the second light source.

The second light source may be disposed at the center between the two adjacent first light sources among the plurality of first light sources.

The second light source may be disposed to correspond to a halfway point of the display panel in the first direction A and correspond to a halfway point of the display panel in the second direction.

The light source device may be provided as a plurality of light source devices. The plurality of light source devices may be disposed to be spaced apart from one another in the second direction. The second light source of each of the light source devices may be disposed to correspond to a halfway point of the display panel in the first direction.

The second light source may be disposed at a point spaced apart from a short side of the display panel by a ⅙ length of the display panel in the first direction. The second light source may be disposed to correspond to a point spaced apart from a long side of the display panel by a ⅙ length of the display panel in the second direction.

The second light source may be provided as a plurality of second light sources. Any one of the plurality of second light sources may be disposed to correspond to a halfway point of the display panel in the first direction. Another of the plurality of second light sources may be disposed to correspond to a point spaced apart from the first short side of the display panel by a ⅙ length of the display panel in the first direction. Still another of the plurality of second light sources may be disposed to correspond to a point spaced apart from the second short side of the display panel by a ⅙ length of the display panel in the first direction.

The plurality of second light sources may be disposed to correspond to a halfway point of the display panel in the second direction B.

The plurality of second light sources may be disposed to correspond to a point spaced apart from a long side of the display panel by a ⅙ length of the display panel in the second direction.

The light source device may be provided as a plurality of light source devices. The plurality of light source devices may be disposed to be spaced apart from one another in the second direction. The plurality of second light sources of any one of the plurality of light source devices may be disposed to correspond to a halfway point of the display panel in the second direction. The plurality of second light sources of another of the plurality of light source devices may be disposed to correspond to a point spaced apart from the first long side of the display panel by a ⅙ length of the display panel in the second direction. The plurality of second light sources of still another of the plurality of light source devices may be disposed to correspond to a point spaced apart from the second long side of the display panel by a ⅙ length of the display panel in the second direction.

The anisotropic reflection lens may include the bottom portion seated on the substrate. The anisotropic reflection lens may include the groove portion recessed from the bottom portion to accommodate the first light-emitting diode.

The first length of the groove portion in the first direction may be shorter than the second length of the groove portion in the second direction.

The anisotropic reflection lens may include a recessed shape. The refractive lens may include a dome shape.

The light source device may be provided as a plurality of light source devices. The plurality of substrates may each include a bar shape extending in the first direction. The plurality of substrates may be disposed to be spaced apart from one another in the second direction.

The light source device may be provided as a plurality of light source devices. The plurality of substrates may each include a plate shape having a plane in the first direction and the second direction.

The display apparatus according to an embodiment of the present disclosure may include the display panel including the pair of long sides extending in the first direction and the pair of short sides extending in the second direction, and the light source device disposed rearward of the display panel. The light source device may include the plurality of first light sources disposed to be spaced apart from one another at the first distance in the first direction. The light source device may include the second light source disposed to be spaced apart from any one of the plurality of first light sources in the first direction at the second distance shorter than the first distance. The plurality of first light sources may each include the first light-emitting diode, and the anisotropic reflection lens provided to cover the first light-emitting diode. The second light source may include the second light-emitting diode, and the refractive lens provided to cover the second light-emitting diode.

The second light source may be disposed between the two adjacent first light sources among the plurality of first light sources.

The second light source may be disposed to correspond to a halfway point of the display panel in the first direction A and correspond to a halfway point of the display panel in the second direction.

The second light source may be disposed at a point spaced apart from a short side of the display panel by a ⅙ length of the display panel in the first direction. The second light source may be disposed to correspond to a point spaced apart from a long side of the display panel by a ⅙ length of the display panel in the second direction.

The anisotropic reflection lens may include the groove portion configured to accommodate the first light-emitting diode. The groove portion may have the first length in the first direction, and the second length longer than the first length in the second direction.

According to an embodiment of the present disclosure, the display apparatus may have the light source device with the improved structure.

According to an embodiment of the present disclosure, the light source device may include the plurality of anisotropic reflection lenses and at least one refractive lens. At least one refractive lens is disposed between the anisotropic reflection lenses, which may reduce or prevent a loss of luminance of the display apparatus. For example, the anisotropic reflection lens may guide most of the light in an approximately vertical direction and/or horizontal direction, and the refractive lens may guide most of the light forward. Therefore, the luminous efficiency of the display apparatus may be improved. In addition, the display apparatus may be implemented to have uniform luminance.

The effects obtained by the present disclosure are not limited to the aforementioned effects, and other effects, which are not mentioned above, will be clearly understood by those skilled in the art.

The particular embodiment has been illustrated and described above.

However, the present disclosure is not limited to the foregoing embodiments, and those skilled in the art will recognize that various modifications can be made without departing from the technical spirit of the present disclosure as set forth in the following claims.

What is claimed is:

1. A display apparatus comprising:
a display panel; and
a light source device configured to provide light to the display panel,
wherein the light source device comprises:
a substrate;
a plurality of first light sources on the substrate, each first light source of the plurality of first light sources comprising a first light-emitting diode and an anisotropic reflection lens configured to cover the first light-emitting diode; and
a second light source on the substrate and between two adjacent first light sources among the plurality of first light sources, the second light source comprising a second light-emitting diode and a refractive lens configured to cover the second light-emitting diode.

2. The display apparatus of claim 1, wherein the display panel comprises:
a pair of long sides extending in a first direction; and
a pair of short sides extending in a second direction,
wherein the plurality of first light sources are spaced apart from each other in the first direction, and
wherein among the plurality of first light sources, a first distance in the first direction between one first light source and another first light source adjacent to the one first light source is longer than a second distance in the first direction between the second light source and another first light source adjacent to the second light source.

3. The display apparatus of claim 1, wherein the second light source is at a center between the two adjacent first light sources among the plurality of first light sources.

4. The display apparatus of claim 2, wherein the second light source is disposed to correspond to a halfway point of the display panel in the first direction and correspond to a halfway point of the display panel in the second direction.

5. The display apparatus of claim 2, wherein the light source device is provided as a plurality of light source devices,
wherein the plurality of light source devices are spaced apart from each other in the second direction, and
wherein the second light source of each light source device of the plurality of light source devices is disposed to correspond to a halfway point of the display panel in the first direction.

6. The display apparatus of claim 2, wherein the second light source is provided to correspond to a point spaced apart from a short side of the display panel by a ⅙ length of the display panel in the first direction and correspond to a point spaced apart from a long side of the display panel by a ⅙ length of the display panel in the second direction.

7. The display apparatus of claim 2, wherein the second light source is provided as a plurality of second light sources,
wherein any one second light source of the plurality of second light sources is disposed to correspond to a halfway point of the display panel in the first direction,
wherein another second light source of the plurality of second light sources is disposed to correspond to a point spaced apart from a first short side of the display panel by a ⅙ length of the display panel in the first direction, and
wherein still another second light source of the plurality of second light sources is disposed to correspond to a point spaced apart from a second short side of the display panel by a ⅙ length of the display panel in the first direction.

8. The display apparatus of claim 7, wherein the plurality of second light sources are disposed to correspond to a halfway point of the display panel in the second direction.

9. The display apparatus of claim 7, wherein the plurality of second light sources are disposed to correspond to a point spaced apart from a long side of the display panel by a ⅙ length of the display panel in the second direction.

10. The display apparatus of claim 8, wherein the light source device is provided as a plurality of light source devices,
wherein the plurality of light source devices are spaced apart from one another in the second direction,
wherein the plurality of second light sources of any one of the plurality of light source devices are disposed to correspond to a halfway point of the display panel in the second direction,
wherein the plurality of second light sources of another light source of the plurality of light source devices are each disposed to correspond to a point spaced apart from a first long side of the display panel by a ⅙ length of the display panel in the second direction, and
wherein the plurality of second light sources of still another light source of the plurality of light source devices are each disposed to correspond to a point spaced apart from a second long side of the display panel by a ⅙ length of the display panel in the second direction.

11. The display apparatus of claim 2, wherein the anisotropic reflection lens comprises:
a bottom portion on the substrate; and
a groove portion recessed from the bottom portion to accommodate the first light-emitting diode.

12. The display apparatus of claim 11, wherein a first length of the groove portion in the first direction is shorter than a second length of the groove portion in the second direction.

13. The display apparatus of claim 1, wherein the anisotropic reflection lens has a recessed shape, and
wherein the refractive lens has a dome shape.

14. The display apparatus of claim 2, wherein the light source device is provided as a plurality of light source devices,
wherein each substrate of a plurality of substrates has a bar shape extending in the first direction, and
wherein the plurality of substrates are spaced apart from one another in the second direction.

15. The display apparatus of claim 2, wherein the light source device is provided as a plurality of light source devices, and
wherein each substrate of a plurality of substrates have a plate shape having a plane in the first direction and the second direction.
